(19) United States
(12) Patent Application Publication
(10) Pub. No.: US 2023/0305049 A1
(43) Pub. Date: Sep. 28, 2023

(54) POWER SUPPLY APPARATUS, SYSTEM INCLUDING POWER SUPPLY APPARATUS, AND INSULATION RESISTANCE DIAGNOSTIC METHOD FOR DIAGNOSING INSULATION RESISTANCE OF POWER SUPPLY APPARATUS

(71) Applicant: ISUZU MOTORS LIMITED, Kanagawa (JP)

(72) Inventors: Takuya KIKUCHI, Fujisawa-shi (JP); Futoshi YAMANE, Fujisawa-shi (JP)

(21) Appl. No.: 18/186,324

(22) Filed: Mar. 20, 2023

(30) Foreign Application Priority Data
Mar. 22, 2022 (JP) 2022-045919

(51) Int. Cl. G01R 31/00; G07C 5/08; G01R 31/389

(52) U.S. Cl. CPC G01R 31/006; G07C 5/0808; G01R 31/389

(57) ABSTRACT

A power supply apparatus, a system including the power supply apparatus, and an insulation resistance diagnostic method for diagnosing an insulation resistance of the power supply apparatus are capable of shortening shutdown time of the system. The power supply apparatus that includes a battery and in which electric power supply is performed between the battery and high-voltage equipment includes: a control section configured to control switching of electrical connection/disconnection between the battery and the high-voltage equipment; and an insulation resistance diagnostic section configured to diagnose an insulation resistance of the battery after the battery and the high-voltage equipment are electrically disconnected from each other. For example, in a system including the power supply apparatus, the insulation resistance diagnostic section further diagnoses the insulation resistance of the battery after shutdown of the system is completed.

### TECHNICAL FIELD

The present disclosure relates to a power supply apparatus, a system including the power supply apparatus, and an insulation resistance diagnostic method of diagnosing insulation resistance of the power supply apparatus.

### BACKGROUND ART

Conventionally, a power supply apparatus in which electric power supply is performed between a battery and high-voltage equipment is known. In order to ensure safety, the battery is covered with an insulating case.

In order to confirm that the insulating property of the battery is sufficiently secured, Patent Literature (hereinafter, referred to as “PTL”) 1 discloses a method for diagnosing the insulating state of the battery.

### CITATION LIST

### Patent Literature

### PTL 1

Japanese Unexamined Patent Application Publication (Translation of PCT Application) No. 2021-503596

### SUMMARY OF INVENTION

### Technical Problem

Meanwhile, in a system including a power supply apparatus (for example, an electric vehicle or a hybrid vehicle equipped with a power supply apparatus), a shutdown control of the system is performed when driving of the vehicle is stopped and a key-off operation is performed. There is a problem that, when an insulation resistance diagnosis on the battery is performed during the shutdown control of the system, the shutdown time of the system becomes longer by the time required for the insulation resistance diagnosis.

An object of the present disclosure is to provide a power supply apparatus capable of shortening a shutdown time of a system, a system including the power supply apparatus, and an insulation resistance diagnostic method of diagnosing insulation resistance of the power supply apparatus.

### Solution to Problem

In order to achieve the above object, a power supply apparatus according to the present disclosure is
a power supply apparatus that includes a battery and in which electric power supply is performed between the battery and high-voltage equipment, the power supply apparatus including:
a control section configured to control switching of electrical connection/disconnection between the battery and the high-voltage equipment; and
an insulation resistance diagnostic section configured to diagnose an insulation resistance of the battery after the battery and the high-voltage equipment are electrically disconnected from each other.

A system according to the present disclosure includes the above-described power supply apparatus, in which
the insulation resistance diagnostic section further diagnoses the insulation resistance of the battery after shutdown of the system is completed.

An insulation resistance diagnostic method for diagnosing insulation resistance of a power supply apparatus according to the present disclosure is
an insulation resistance diagnostic method for diagnosing an insulation resistance of a power supply apparatus that includes a battery and in which electric power supply is performed between the battery and high-voltage equipment, the insulation resistance diagnostic method including:
controlling switching of electrical connection/disconnection between the battery and the high-voltage equipment; and
diagnosing the insulation resistance of the battery after the battery and the high-voltage equipment are electrically disconnected from each other.

### Advantageous Effects of Invention

According to the present disclosure, it is possible to shorten shutdown time of a system.

### BRIEF DESCRIPTION OF DRAWINGS

FIG. 1 is a diagram illustrating a configuration of a power supply apparatus according to an embodiment of the present disclosure; and

FIG. 2 is a diagram illustrating one example of a shutdown control of a system according to a comparative example and a shutdown control of a system according to the present embodiment.

### DESCRIPTION OF EMBODIMENTS

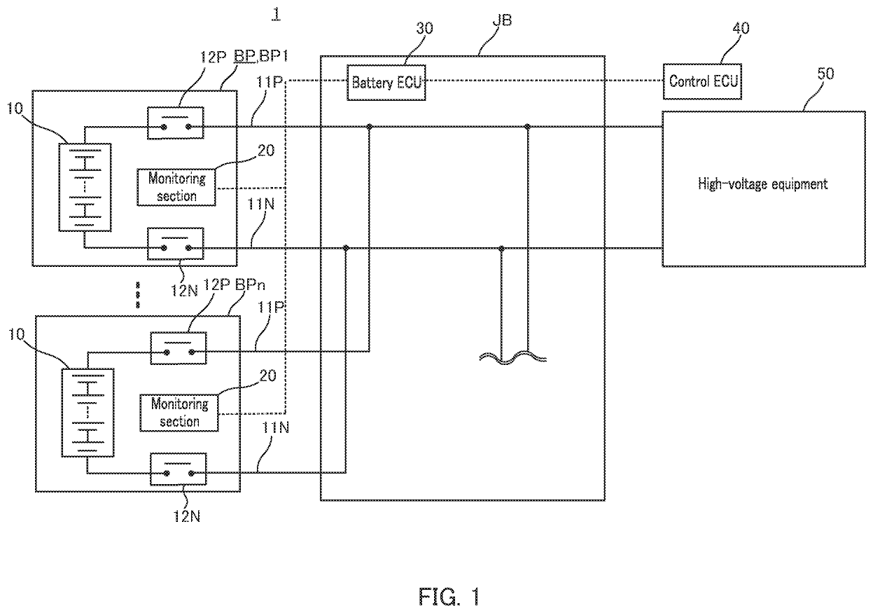

Hereinafter, embodiments of the present disclosure will be described with reference to the drawings. FIG. 1 is a block diagram illustrating power supply apparatus 1 according to an embodiment of the present disclosure.

Power supply apparatus 1 illustrated in FIG. 1 is mounted, for example, in a vehicle such as an electric vehicle or a hybrid vehicle. In the present embodiment, the vehicle will be described as one example of a system including power supply apparatus 1.

Power supply apparatus 1 includes battery packs BP. FIG. 1 illustrates n battery packs BP1, . . . , BPn. Note that n is an integer equal to or greater than two. Each of battery packs BP includes battery 10 and monitoring section 20. Battery pack BP is covered around by an insulating case.

Battery 10 is composed of a plurality of lithium ion battery cells connected in series to one another. Positive-side power supply line 11P is drawn from a positive-side terminal of a series circuit of battery 10. Negative-side power supply line 11N is drawn from a negative-side terminal of the series circuit of battery 10. Positive-side relay 12P is connected to positive-side power supply line 11P. Negative-side relay 12N is connected to negative-side power supply line 11N.

Positive-side relay 12P and negative-side relay 12N are connected to high-voltage equipment 50 such as a motor driving section, a DC/DC converter, a charger, an electric mounting, a Positive Temperature Coefficient (PTC) heater, and an air compressor via junction box JB.

[Monitoring Section 20]

Monitoring section 20 is mounted on each of a plurality of battery packs BP, and monitors and controls battery pack BP. Monitoring section 20 includes a Central Processing Unit (CPU), a Read Only Memory (ROM), a Random Access Memory (RAM), and the like. The CPU reads a program suited to processing contents out of the ROM and develops the program in the RAM, to execute predetermined functions of monitoring section 20 in cooperation with the developed program.

Monitoring section 20 includes a function of adjusting a voltage of each of the plurality of lithium ion battery cells, a function of monitoring a current, a voltage, and a temperature in battery pack BP, a function of controlling a charging and discharging current of battery pack BP, a function of detecting an insulation resistance of battery pack BP (corresponding to an “insulation resistance diagnostic section” of the present disclosure), and a function of controlling ON/OFF of relays (including positive-side relay 12P and negative-side relay 12N) in battery pack BP (corresponding to a “control section” of the present disclosure).

When each of positive-side relay 12P and negative-side relay 12N is turned on, battery packs BP and the high-voltage equipment are electrically connected to each other. When either positive-side relay 12P or negative-side relay 12N is turned off, battery packs BP and the high-voltage equipment are electrically disconnected from each other.

The insulation resistance diagnosis for diagnosing the insulation resistance of battery pack BP is performed by a known method after battery packs BP and the high-voltage equipment are electrically disconnected from each other. The insulation resistance diagnosis is performed, for example, by measuring an insulation resistance between a housing (insulator) of battery pack BP and a conductive portion (e.g., a live portion such as a cell) included in battery pack BP.

[Battery ECU 30]

Battery ECU 30 includes a Central Processing Unit (CPU), a Read Only Memory (ROM), a Random Access Memory (RAM), and the like. The CPU reads a program suited to processing contents out of the ROM and develops the program in the RAM, to execute predetermined functions of battery ECU 30 in cooperation with the developed program. At this time, various data stored in a storage section (not illustrated) is referred to. The storage section includes, for example, a nonvolatile semiconductor memory (so-called flash memory) or a hard disk drive. Battery ECU 30 may be incorporated in, for example, a vehicle Electronic Control Unit (ECU) that controls each section of the vehicle, may be configured integrally with control ECU 40, or may be provided separately from the vehicle ECU and control ECU 40.

Battery ECU 30 has a function of controlling communication with control ECU 40, monitoring a current in junction box JB, turning on and off relays in junction box JB, and the like.

[Control ECU 40]

Control ECU 40 includes a Central Processing Unit (CPU), a Read Only Memory (ROM), a Random Access Memory (RAM), and the like. The CPU reads a program suited to processing contents out of the ROM and develops the program in the RAM, to execute predetermined functions of control ECU 40 in cooperation with the developed program. At this time, various data stored in the storage section (not illustrated) is referred to. The storage section includes, for example, a nonvolatile semiconductor memory (so-called flash memory) or a hard disk drive. Control ECU 40 may be incorporated in, for example, the vehicle Electronic Control Unit (ECU) that controls each section of the vehicle, may be configured integrally with battery ECU 30, or may be provided separately from the vehicle ECU and battery ECU 30.

The vehicle ECU performs a process of stopping the ECUs such as battery ECU 30 and control ECU 40, and a shutdown process of shutting down the ECUs.

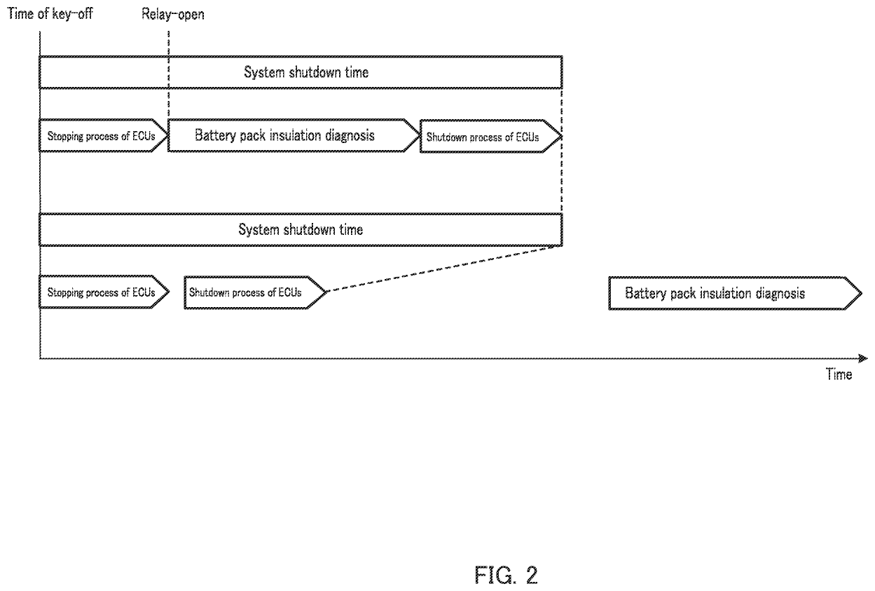

FIG. 2 is a diagram illustrating one example of a shutdown control of a system according to a comparative example and a shutdown control of the system according to the present embodiment. The “Relay open” illustrated in FIG. 2 means that either positive-side relay 12P or negative-side relay 12N is turned off. When driving of the vehicle is ended and a key-off operation is performed, the shutdown control of the system is performed. In the shutdown control of the comparative example illustrated at the upper side in FIG. 2, a stopping process for stopping the ECUs such as battery ECU 30 and control ECU 40 are performed first. Next, the insulation resistance diagnosis on above-described battery packs BP is performed. Next, the shutdown process for shutting down the ECUs is performed. As described above, when the insulation resistance diagnosis on battery packs BP is performed during the shutdown control of the system, the shutdown time of the system is prolonged by the time required for the insulation resistance diagnosis. In the comparative example, after the stopping process for stopping the ECUs is performed, the insulation resistance diagnosis on battery packs BP is started.

During the shutdown control on the system according to the present embodiment illustrated at the lower part in FIG. 2, the stopping process on the ECUs and the shutdown process on the ECUs are performed, but the insulation resistance diagnosis on battery packs BP is not performed. In the present embodiment, the insulation resistance diagnosis on battery packs BP is performed after the elapse of the shutdown time of the system. In other words, the insulation resistance diagnosis is performed after completion of the shutdown of elements other than battery packs BP.

Power supply apparatus 1 according to the embodiment of the present disclosure is a power supply apparatus that includes battery packs BP and in which electric power supply is performed between battery packs BP and high-voltage equipment 50, the power supply apparatus including a control section configured to control switching of electrical connection/disconnection between battery packs BP and high-voltage equipment 50, and an insulation resistance diagnostic section configured to diagnose an insulation resistance of battery packs BP after battery packs BP and high-voltage equipment 50 are electrically disconnected from each other.

According to the above configuration, the insulation resistances of battery packs BP are diagnosed after battery packs BP and high-voltage equipment 50 are electrically disconnected from each other. Thus, the insulation resistances of battery packs BP can be accurately measured.

In addition, in power supply apparatus 1 according to the embodiment of the present disclosure, the insulation resistance diagnostic section is further configured to diagnose the insulation resistances of the batteries after the shutdown of the system is completed. This makes it possible to shorten the shutdown time of the system.

In addition, the aforementioned embodiments merely describe examples of implementations for practicing the present disclosure, and should not be construed as limiting the technical scope of the present disclosure. In other words, the present disclosure can be implemented in various forms without departing from the scope, or essential features thereof.

This application is based on Japanese Patent Application No. 2022-045919 filed on Mar. 22, 2022, the disclosure of which including the specification, drawings and abstract is incorporated herein by reference in its entirety.

### INDUSTRIAL APPLICABILITY

The present disclosure is suitably used for a vehicle provided with a power supply apparatus that is required to shorten shutdown time of the vehicle.

### REFERENCE SIGNS LIST

BP, BP1, . . . , BPn Battery pack
1 Power supply apparatus
10 Battery
11P Positive-side power supply line
11N Negative-side power supply line
12P Positive-side relay
12N Negative-side relay
20 Monitoring section
30 Battery ECU
40 Vehicle ECU
50 High-voltage equipment

What is claimed is:

1. A power supply apparatus that includes a battery and in which electric power supply is performed between the battery and high-voltage equipment, the power supply apparatus comprising:
a control section configured to control switching of electrical connection/disconnection between the battery and the high-voltage equipment; and
an insulation resistance diagnostic section configured to diagnose an insulation resistance of the battery after the battery and the high-voltage equipment are electrically disconnected from each other.

2. A system, comprising:
a power supply apparatus according to claim 1, wherein
the insulation resistance diagnostic section is further configured to diagnose the insulation resistance of the battery after shutdown of the system is completed.

3. An insulation resistance diagnostic method for diagnosing an insulation resistance of a power supply apparatus that includes a battery and in which electric power supply is performed between the battery and high-voltage equipment, the insulation resistance diagnostic method comprising:
controlling switching of electrical connection/disconnection between the battery and the high-voltage equipment; and
diagnosing the insulation resistance of the battery after the battery and the high-voltage equipment are electrically disconnected from each other.
